(19) United States
(12) Patent Application Publication
(10) Pub. No.: US 2023/0387031 A1
(43) Pub. Date: Nov. 30, 2023

(54) SEMICONDUCTOR PACKAGE CROSSTALK REDUCTION

(71) Applicant: Taiwan Semiconductor Manufacturing Company, Ltd., Hsinchu (TW)

(72) Inventors: Shu-Chun Yang, Changhua County (TW); Wei Chih Chen, Hsinchu City (TW)

(21) Appl. No.: 17/824,353

(22) Filed: May 25, 2022

(51) Int. Cl. H01L 23/538; H01L 23/00; H01L 23/498; H01L 25/065; H01L 21/48

(52) U.S. Cl. CPC H01L 23/5386; H01L 24/24; H01L 24/19; H01L 23/49816; H01L 23/49822; H01L 23/49833; H01L 23/49838; H01L 23/5385; H01L 25/0655; H01L 21/4857; H01L 21/486; H01L 2924/3025; H01L 24/16; H01L 24/32; H01L 24/73; H01L 2224/24137; H01L 2224/16225; H01L 2224/32225; H01L 2224/73204

(57) ABSTRACT

A semiconductor package according to the present disclosure includes a routing structure, a first die and a second die disposed over the routing structure, a first array of contact features disposed along a first direction and electrically coupling the first die to the routing structure, and a second array of contact features disposed along the first direction and electrically coupling the second die to the routing structure. The routing structure includes a plurality of metal lines and each of the plurality of metal lines electrically connects one of the first array of contact features and one of the second array of contact features. Each of the plurality of metal lines comprises at least two 90-degree turns on a horizontal plane.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Due to the miniaturized scale of the semiconductor device, more than one IC chip may be integrated into a semiconductor package. In some instances, the chip-to-chip communication between the IC chips being integrated may be provided by way of an interposer or a redistribution layer (RDL) structure. The chip-to-chip communication involves not only conductive features carrying logic signals but also those carrying input/output (I/O) signals. While existing chip-to-chip communication in semiconductor packages is generally adequate for their intended purposes, it is not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a first example semiconductor package structure, according to various aspects of the present disclosure.

FIG. 2 illustrates a second example semiconductor package structure, according to various aspects of the present disclosure.

FIGS. 3, 4 and 5 illustrate example wide bus I/O routing arrangements, according to various aspects of the present disclosure.

FIG. 6 schematically illustrates insertion of a ground metal line between two adjacent signal lines in a same metallization layer, according to various aspects of the present disclosure.

FIGS. 7, 8 and 9 schematically illustrate different signal-to-ground ratios in terms of microbumps or vias on a semiconductor package, according to various aspects of the present disclosure.

FIG. 10 schematically illustrates comparative crosstalk levels at different signal-to-ground ratios shown in FIGS. 7, 8 and 9, according to various aspects of the present disclosure.

FIG. 11 schematically illustrates a first wide bus I/O routing arrangement in an RDL structure of the first example semiconductor package in FIG. 1, according to various aspects of the present disclosure.

FIG. 12 schematically illustrates a second wide bus I/O routing arrangement in an RDL structure of the first example semiconductor package in FIG. 1, according to various aspects of the present disclosure.

FIG. 13 schematically illustrates comparative crosstalk levels using the first wide bus I/O routing arrangement in FIG. 11 or the second wide bus I/O routing arrangement in FIG. 12, according to various aspects of the present disclosure.

FIG. 14 schematically illustrates a first wide bus I/O routing arrangement in an interposer of the second example semiconductor package in FIG. 2, according to various aspects of the present disclosure.

FIG. 15 schematically illustrates a second wide bus I/O routing arrangement in an interposer of the second example semiconductor package in FIG. 2, according to various aspects of the present disclosure.

FIG. 16 schematically illustrates a third wide bus I/O routing arrangement in an interposer of the second example semiconductor package in FIG. 2, according to various aspects of the present disclosure.

FIG. 17 schematically illustrates comparative crosstalk levels using the first wide bus I/O routing arrangement in FIG. 14, the second wide bus I/O routing arrangement in FIG. 15 or the third wide bus I/O routing arrangement in FIG. 16, according to various aspects of the present disclosure.

FIG. 18 is a flowchart for a method 400 for forming metal lines similar to those shown in FIGS. 3, 4, and 5 to achieve chip-to-chip communication, according to various aspects of the present application.

FIGS. 19, 20 and 21 illustrate a workpiece for a redistribution layer undergoing various operations of the method 400 of FIG. 18, according to various aspects of the present application.

FIGS. 22, 23 and 24 illustrate a workpiece for an interposer undergoing various operations of the method 400 of FIG. 18, according to various aspects of the present application.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Semiconductor packaging technologies were once just considered backend processes that facilitates chips to interface external circuitry. Times have changed. Computing workloads have evolved so much that brought packaging technologies to the forefront of innovation. Modern packaging provides integration of multiple chips or dies into a single semiconductor device. Depending on the level of stacking, modern semiconductor packages can have a 2.5D structure or a 3D structure. In a 2.5D structure, at least two dies are coupled to a redistribution layer (RDL) structure or an interposer that provides chip-to-chip communication. The at least two dies in a 2.5D structure are not stacked one over another vertically. In a 3D structure, at least two dies are stacked one over another and interact with each other by way of through silicon vias (TSVs). Depending on the processes adopted, the 2.5D structure and the 3D structure may have an Integrated Fan-Out (InFO) construction or a Chip-on-Wafer-on-Substrate (CoWoS®) construction. When the former is adopted, an RDL structure is formed over the front surface of the die(s) and the die(s) is electrically coupled to the RDL structure by way of vias embedded in a dielectric layer. When the latter is adopted, die(s) are bonded to a separately formed interposer by way of microbumps.

In 2.5D semiconductor packages, chip-to-chip communication (or die-to-die communication) is provided by the RDL structure or the interposer. The use of RDL structures and interposer is not without challenges. First, in high speed applications, difference in metal lines may cause clock skew (also known as timing skew) where the same sourced clock signal arrive at different components at different times due to signal propagation delay. Second, signal lines in the RDL structure or the interposer may be too closely disposed to cause crosstalk and a reduced signal-to-noise ratio. Third, because cost associated with formation metallization layers in an RDL structure or an interposer increases with the scaling down of devices, it is desirable to have less than more metallization layers.

The present disclosure provides several aspects of improvement to chip-to-chip communication in semiconductor packages. In one aspect, the present disclosure provides same-level electrical routing between two chips that does not require formation of additional vias to change metallization layers and does not introduce any clock skew. In another aspects, the present disclosure provides insertion of ground/power between signal lines or contact features to provide current return path and to reduce crosstalk. The reduction of skew and crosstalk provides an improved input/output (I/O) bandwidth of the semiconductor package.

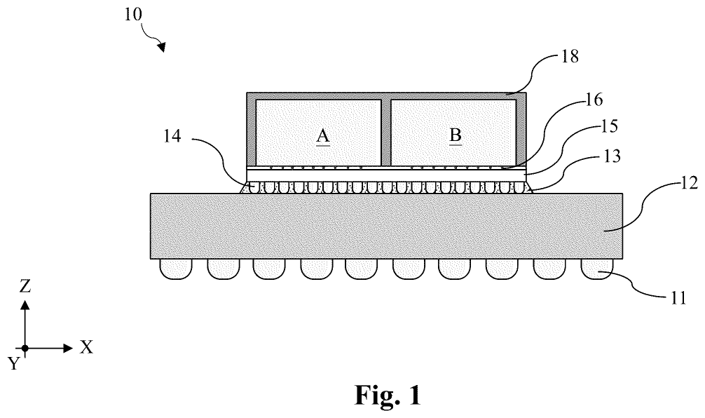

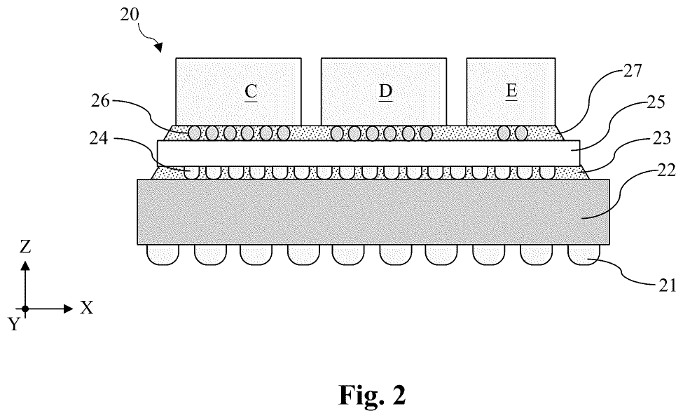

FIGS. 1 and 2 illustrate semiconductor device package structures where a routing structure provides chip-to-chip communication between two chips disposed on the routing structure. FIG. 1 shows a schematic cross-sectional view of a semiconductor device package structure 10. The semiconductor device package structure 10 includes a chip A (or a die A) and a chip B (or a die B) disposed side-by-side over an RDL structure 15. Each of the chip A and chip B is electrically coupled to the RDL structure 15 by way of contact vias 16. The RDL structure 15 is then bonded to a substrate 12 via a plurality of controlled collapse chip connection (C4) bumps 14, which are protected by an underfill layer 13. In some alternative embodiments, the C4 bumps 24 may be replaced with microbumps. The substrate 12 may be a printed circuit board (PCB) substrate 12 and may further include ball grid arrays (BGAs) 11 to further bond to other external circuitry. In an example process, the contact vias 16 and the RDL structure 15 may be fabricated over front surfaces of the chip A and the chip B by depositing dielectric layers, forming openings in the dielectric layers, depositing a conductive material over the openings, and planarization. After the C4 bumps 14 are formed over the top surface of the RDL structure 15, the RDL structure 15, along with the chip A and chip B, is flipped upside down to bond to the substrate 12. It can be from FIG. 1 that the RDL structure 15 provides chip-to-chip communication along the X direction between the chip A and the chip B.

FIG. 2 illustrates a schematic cross-sectional view of a semiconductor device package structure 20. The semiconductor device package structure 20 includes a chip C (or a die C), a chip D (or a die D), or a chip E (or a die E) disposed side-by-side over an interposer 25, which may be a silicon interposer or a silicon-less interposer. Similar to the RDL structure 15, the interposer 25 includes multiple metal layers. The chips C, D and E are individually flipped-over and coupled to the interposer 25 by way of microbumps 26, which may be protected by a first underfill layer 27. The interposer 25 is then electrically coupled to a substrate 22 by way of a plurality of controlled collapse chip connection (C4) bumps 24, which are protected by a second underfill layer 23. In some alternative embodiments, the C4 bumps 24 may be replaced with microbumps. The substrate 22 may be a printed circuit board (PCB) substrate 22 and may further include ball grid arrays (BGAs) 21 to further bond to other external circuitry. In an example process, the chips C, D and E are first bonded to the interposer 25 by way of the microbumps 26. After the first underfill layer 27 is formed, the chips C, D and E are bonded to a carrier substrate and the interposer 25 is grounded to expose the contact features. C4 bumps 24 are then formed over the exposed contact features and the carrier substrate is removed. The interposer 25, along with the chips C, D and E, is then flipped over and bonded to a substrate 22 by way of the C4 bumps 24. It can be from FIG. 2 that the interposer 25 provides chip-to-chip communication along the X direction between the chip C and the chip D and between the chip D and the chip E.

In some embodiments, the contact vias 16 in FIG. 1 or the microbumps 26 in FIG. 2 may arranged as a rectangular array that has a constant pitch and a uniform spacing. The constant pitch and uniform spacing may be maintained along both directions on a horizontal plane. In some conventional structures, chip-to-chip communication is not provided in the metal layer of the RDL structure or the interposer that is closer to the chips. This is so because vias in the topmost metal layer of the RDL structure or the interposer are first formed to route the signal from the chip(s) to a metal layer farther away from the chips to allow a straight line connection. In these conventional structures, the straight lines can be kept the same length to eliminate or reduce clock skew. This conventional structure, however, may prevent the topmost metal layer to provide chip-to-chip communication. This underusage is not conducive to reduction of metal layers in the RDL structure or the interposer.

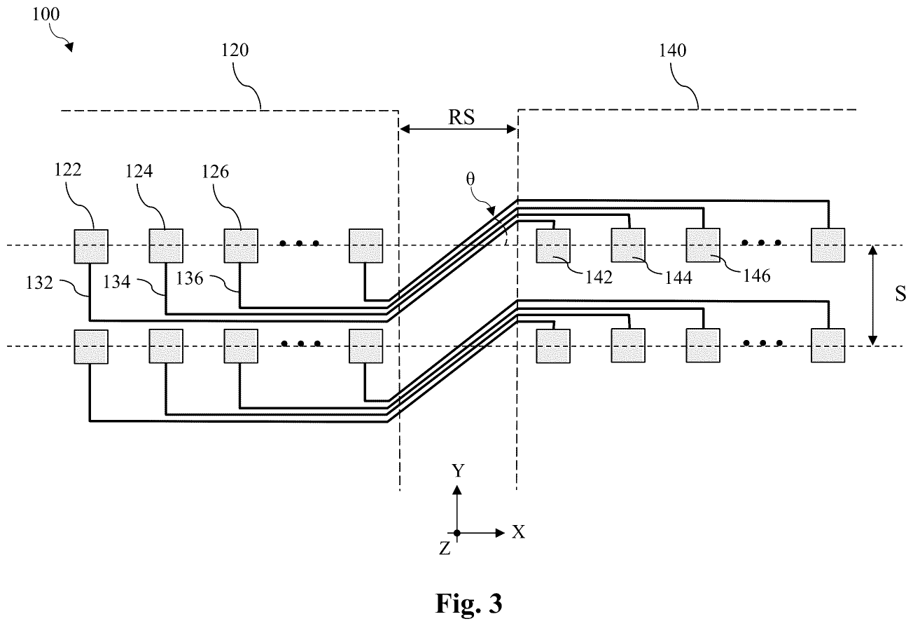

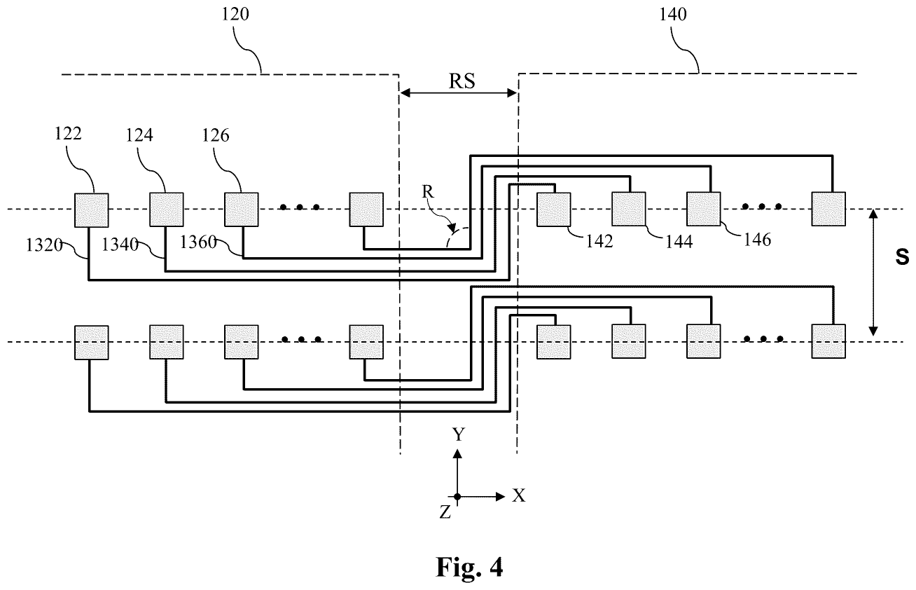

To make better use of the topmost metal layer, the present disclosure provides example routing structures shown in FIGS. 3 and 4. FIG. 3 illustrates a first routing structure on a device package 100. In the implementations represented in FIG. 3, the device package 100 includes a first chip 120 and a second chip 140. The first chip 120 and the second chip 140 represent two side-by-side chips in a 2.5D construction. That is, the first chip 120 and the second chip 140 may correspond to chip A and chip B shown in FIG. 1, chip C and Chip D shown in FIG. 2, or chip D and chip E shown in FIG. 2. While not shown, each of the first chip 120 and the second chip 140 are disposed on or electrically coupled to a routing structure, such as the RDL structure 15 shown in FIG. 1 or the interposer 25 shown in FIG. 2. The electrical connection between the chips (i.e., the first chip 120 and the second chip 140) and the routing structure are achieved by arrays of contact features. For example, the first chip 120 is electrically coupled to the routing structure by way of first contact features 122, 124 and 126 and the other similarly situated contact features. The second chip 140 is electrically coupled to the routing structure by way of second contact features 142, 144 and 146 and the other similarly situated contact features. Depending on the construction and the fabrication processes, the first contact features 122, 124 and 126 and the second contact features 142, 144, and 146 may correspond to the contact vias shown in FIG. 1 or the microbumps 26 shown in FIG. 2. It is noted that FIG. 3 only schematically illustrates a portion of the first chip 120 and a portion of the second chip 140. For that reason, the boundaries of the first chip 120 and the second chip 140 in FIG. 3 are open-ended and not closed.

To provide a uniform routing environment and process loading, the first contact features and the second contact features are each arranged in a rectangular array with a uniform feature-to-feature spacing S. It is noted that FIG. 3 is not drawn to scale. The first contact features and the second contact features are characterized by the same spacing S along the X direction or the Y direction. The chip-to-chip communication between the first chip 120 and the second chip 140 is achieved by metal lines connecting a first contact feature and a corresponding second contact feature. In the embodiments illustrated in FIG. 3, the first contact feature 122 is electrically connected to the second contact feature 142 by way of a first metal line 132. The first contact feature 124 is electrically connected to the second contact feature 144 by way of a second metal line 134. The first contact feature 126 is electrically connected to the second contact feature 146 by way of a third metal line 136. While not explicitly shown in FIG. 3, the first metal line 132, the second metal line 134, and the third metal line 136 all extend and turn in a same metal layer of the routing structure. That is, the first metal line 132, the second metal line 134, and the third metal line 136 all extend and turn on the same X-Y plane when viewed along the Z direction. In other words, FIG. 3 illustrates a schematic top view of the device package 100. In the depicted embodiment, the first metal line 132 first extends from the first contact feature 122 along the Y direction (downward in FIG. 3) and makes a first 90-degree turn to extend along the X direction (from left to right in FIG. 3). Instead of continuing to extend along the X direction, the first metal line 132 makes two acute-angle turns at degree 0 until it enters into the area right below the second chip 140. Because one of the two acute-angle turns is counterclockwise and the other is clockwise, they cancel each other to allow the first metal line 132 to extend along the X direction again. Once entering the area of the second chip 140, the first metal line 132 continues to extend along the X direction until it makes a second 90-degree-turn (downward in FIG. 3) to couple to the second contact feature 142. As shown in FIG. 3, due to the two acute-angle turns, the first metal line 132 changes from extending horizontally below the first contact features (i.e., 122, 124 and 126) to extending horizontally above the second contact features (i.e., 142, 144 and 146) even though the first contact features are aligned with the second contact features along the X direction.

The second metal line 134 and the third metal line 136 achieve the same feature-to-feature communication in a similar manner. In the depicted embodiment, the second metal line 134 first extends from the first contact feature 124 along the Y direction (downward in FIG. 3) and makes a first 90-degree turn to extend along the X direction (from left to right in FIG. 3). Instead of continuing to extend along the X direction, the second metal line 134 makes two acute-angle turns at degree 0 until it enters into the area right below the second chip 140. Because one of the two acute-angle turns is counterclockwise and the other is clockwise, they cancel each other to allow the second metal line 134 to extend along the X direction again. Once entering the area of the second chip 140, the second metal line 134 continues to extend along the X direction until it makes a second 90-degree-turn (downward in FIG. 3) to couple to the second contact feature 144. As shown in FIG. 3, due to the two acute-angle turns, the second metal line 134 changes from extending horizontally below the first contact features (i.e., 122, 124 and 126) to extending horizontally above the second contact features (i.e., 142, 144 and 146) even though the first contact features are aligned with the second contact features along the X direction. It can be seen from FIG. 3 that the second metal line 134 generally tracks the shapes of the first metal line 132.

Similarly, the third metal line 136 first extends from the first contact feature 126 along the Y direction (downward in FIG. 3) and makes a first 90-degree turn to extend along the X direction (from left to right in FIG. 3). Instead of continuing to extend along the X direction, the third metal line 136 makes two acute-angle turns at degree 0 until it enters into the area right below the second chip 140. Because one of the two acute-angle turns is counterclockwise and the other is clockwise, they cancel each other to allow the third metal line 136 to extend along the X direction again. Once entering the area of the second chip 140, the third metal line 136 continues to extend along the X direction until it makes a second 90-degree-turn (downward in FIG. 3) to couple to the second contact feature 146. As shown in FIG. 3, due to the two acute-angle turns, the second metal line 134 changes from extending horizontally below the first contact features (i.e., 122, 124 and 126) to extending horizontally above the second contact features (i.e., 142, 144 and 146) even though the first contact features are aligned with the second contact features along the X direction. It can be seen from FIG. 3 that the third metal line 136 generally tracks the shapes of the first metal line 132 and the second metal line 134.

Depending on a routing resource between the first chip 120 and the second chip 140, the acute angle θ may have different values. Referring to FIG. 3, a routing space (RS) between the first chip 120 and the second chip 140 represents the routing resource for chip-to-chip connection. To effectively use the routing space (RS), the two acute angles θ may be spaced apart along the X direction by the entire routing space (RS) or one half (0.5) of the routing space. That is, according to the present disclosure, a lower bound of the acute angle θ can be calculated as tan⁻¹(feature-to-feature spacing S/routing space RS) and an upper bound of the acute angle θ can be calculated as tan⁻¹(feature-to-feature spacing S/(0.5×routing space RS)).

In FIG. 3, the metal lines that provide chip-to-chip communication are of substantially the same length. That is, the total lengths of the first metal line 132, the second metal line 134, and the third metal line 136 are substantially the same. By having the two 90-degree-turns and the two acute-angle turns, the metal lines in FIG. 3 may be disposed in the topmost metal layer in the routing structure. As used herein, the topmost metal layer refers to the metal layer is closest to the chips, such as the first chip 120 and the second chip 140. In some existing structures, vias are needed in the topmost metal layer to couple to straight metal lines in another metal layer farther away from the chips. The metal lines shown in FIG. 3 facilitate reduction of metal layers without introducing additional skew.

FIG. 4 illustrates a second routing structure on a device package 100. Similar to the device package 100 shown in FIG. 3, the device package 100 in FIG. 4 the device package 100 includes a first chip 120 and a second chip 140, which may correspond to chip A and chip B shown in FIG. 1, chip C and Chip D shown in FIG. 2, or chip D and chip E shown in FIG. 2. While not shown, each of the first chip 120 and the second chip 140 are disposed on or electrically coupled to a routing structure, such as the RDL structure 15 shown in FIG. 1 or the interposer 25 shown in FIG. 2. The electrical connection between the chips (i.e., the first chip 120 and the second chip 140) and the routing structure are achieved by arrays of contact features. For example, the first chip 120 is electrically coupled to the routing structure by way of first contact features 122, 124 and 126 and the other similarly situated contact features. The second chip 140 is electrically coupled to the routing structure by way of second contact features 142, 144 and 146 and the other similarly situated contact features. Depending on the construction and the fabrication processes, the first contact features 122, 124 and 126 and the second contact features 142, 144, and 146 may correspond to the contact vias shown in FIG. 1 or the microbumps 26 shown in FIG. 2. The first contact features and the second contact features are each arranged in a rectangular array with a uniform feature-to-feature spacing S.

Similar to the first routing structure shown in FIG. 3, the second routing structure includes metal lines in the same metal layer to achieve the chip-to-chip communication between the first chip 120 and the second chip 140. In the embodiments illustrated in FIG. 4, the first contact feature 122 is electrically connected to the second contact feature 142 by way of a first metal line 1320. The first contact feature 124 is electrically connected to the second contact feature 144 by way of a second metal line 1340. The first contact feature 126 is electrically connected to the second contact feature 146 by way of a third metal line 1360. The first metal line 1320, the second metal line 1340, and the third metal line 1360 all extend and turn on the same X-Y plane when viewed along the Z direction. Different from the first routing structure in FIG. 3, the second routing structure replaces the two acute-angle turns with two right angle (R) turns. In the depicted embodiment, the first metal line 1320 first extends from the first contact feature 122 along the Y direction (downward in FIG. 3) and makes a first 90-degree turn to extend along the X direction (from left to right in FIG. 3). Instead of continuing to extend along the X direction, the first metal line 1320 makes two right-angle turns until it enters into the area right below the second chip 140. Once entering the area of the second chip 140, the first metal line 1320 continues to extend along the X direction until it makes a second 90-degree-turn (downward in FIG. 3) to couple to the second contact feature 142. The second metal line 1340 and the third metal line 1360 achieve the same feature-to-feature communication in a similar manner.

It can be seen from FIG. 4 that the second routing structure may take up more room in the routing space (RS). At the same time, because of the right-angle turns, it may be easier to fabricate the first metal line 1320, the second metal line 1340, and the third metal line 1360 using photolithography and etch processes.

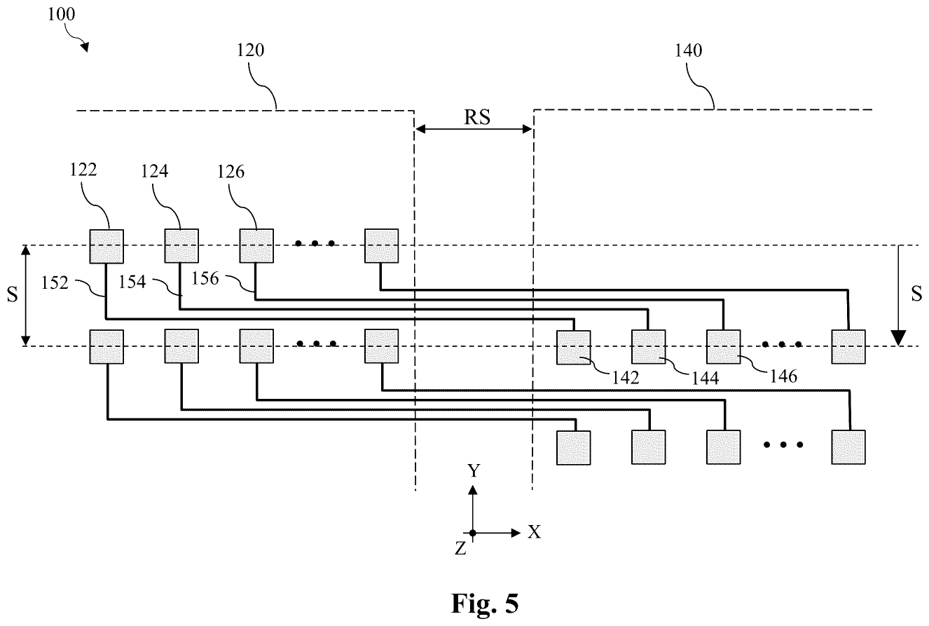

FIG. 5 illustrates a third routing structure on a device package 100. Similar to the device package 100 shown in FIG. 3, the device package 100 in FIG. 5 the device package 100 includes a first chip 120 and a second chip 140, which may correspond to chip A and chip B shown in FIG. 1, chip C and Chip D shown in FIG. 2, or chip D and chip E shown in FIG. 2. While not shown, each of the first chip 120 and the second chip 140 are disposed on or electrically coupled to a routing structure, such as the RDL structure 15 shown in FIG. 1 or the interposer 25 shown in FIG. 2. The electrical connection between the chips (i.e., the first chip 120 and the second chip 140) and the routing structure are achieved by arrays of contact features. For example, the first chip 120 is electrically coupled to the routing structure by way of first contact features 122, 124 and 126 and the other similarly situated contact features. The second chip 140 is electrically coupled to the routing structure by way of second contact features 142, 144 and 146 and the other similarly situated contact features. Depending on the construction and the fabrication processes, the first contact features 122, 124 and 126 and the second contact features 142, 144, and 146 may correspond to the contact vias shown in FIG. 1 or the microbumps 26 shown in FIG. 2. The first contact features and the second contact features are each arranged in a rectangular array with a uniform feature-to-feature spacing S.

Like the device package 100 in FIG. 3, the chip-to-chip communication between the first chip 120 and the second chip 140 in FIG. 5 is achieved by metal lines connecting a first contact feature and a corresponding second contact feature. Different from the first routing structure in FIG. 3, the third routing structure in FIG. 5 utilizes metal lines that are represented by a fourth metal line 152, a fifth metal line 154, and a sixth metal line 156. As shown in FIG. 5, while each of the fourth metal line 152, the fifth metal line 154, and the sixth metal line 156 includes two 90-degree-turns, none of them includes two acute-angle turns like the first metal line 132, the second metal line 134 or the third metal line 136. This is so because the second contact features are not aligned with the first contact features along the X direction. Rather, the second contact features are shifted along the Y direction by the Spacing S. As shown in FIG. 5, the Y-direction shifting causes the second contact features to align with a row of contact features below/adjacent the first contact features. In the embodiments illustrated in FIG. 5, the first contact feature 122 is electrically connected to the second contact feature 142 by way of the fourth metal line 152. The first contact feature 124 is electrically connected to the second contact feature 144 by way of the fifth metal line 154. The first contact feature 126 is electrically connected to the second contact feature 146 by way of the sixth metal line 156. While not explicitly shown in FIG. 5, the fourth metal line 152, the fifth metal line 154, and the sixth metal line 156 all extend and turn in a same metal layer of the routing structure. That is, the fourth metal line 152, the fifth metal line 154, and the sixth metal line 156 all extend and turn on the same X-Y plane when viewed along the Z direction. In other words, FIG. 5 is a schematic top view of the device package 100.

In the depicted embodiment, the fourth metal line 152 first extends from the first contact feature 122 along the Y direction (downward in FIG. 5) and makes a first 90-degree turn to extend along the X direction (from left to right in FIG. 5) all the way into the area right below the second chip 140. Because the second contact features are shifted downward (along the Y direction) by the Spacing S, the fourth metal line 152 does not include the acute angle turns of the first metal line 132. Once the fourth metal line 152 reaches the second contact feature 142 along the X direction, it makes a second 90-degree-turn (downward in FIG. 5) to couple to the second contact feature 142.

The fifth metal line 154 and the sixth metal line 156 achieve the same feature-to-feature communication in a similar manner. In the depicted embodiment, the fifth metal line 154 first extends from the first contact feature 124 along the Y direction (downward in FIG. 5) and makes a first 90-degree turn to extend along the X direction (from left to right in FIG. 5) all the way into the area right below the second chip 140. Because the second contact features are shifted downward (along the Y direction) by the Spacing S, the fifth metal line 154 does not include the acute angle turns of the second metal line 134. Once the fifth metal line 154 reaches the second contact feature 144 along the X direction, it makes a second 90-degree-turn (downward in FIG. 5) to couple to the second contact feature 144.

Similarly, the sixth metal line 156 first extends from the first contact feature 126 along the Y direction (downward in FIG. 5) and makes a first 90-degree turn to extend along the X direction (from left to right in FIG. 5) all the way into the area right below the second chip 140. Because the second contact features are shifted downward (along the Y direction) by the Spacing S, the sixth metal line 156 does not include the acute angle turns of the third metal line 136. Once the sixth metal line 156 reaches the second contact feature 146 along the X direction, it makes a second 90-degree-turn (downward in FIG. 5) to couple to the second contact feature 146. It can be seen from FIG. 5 that the sixth metal line 156 generally tracks the shapes of the fourth metal line 152 and the fifth metal line 154.

In FIG. 5, the metal lines that provide chip-to-chip communication are of substantially the same length. That is, the total lengths of the fourth metal line 152, the fifth metal line 154, and the sixth metal line 156 are substantially the same. By having the two 90-degree-turns, the metal lines in FIG. 5 may be disposed in the topmost metal layer in the routing structure. The metal lines shown in FIG. 5 facilitate reduction of metal layers without introducing additional skew.

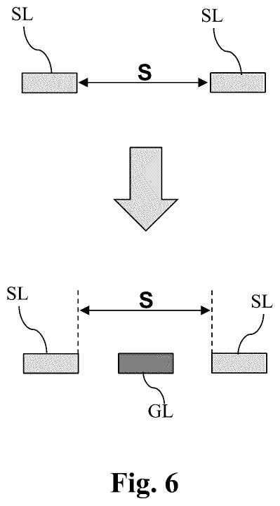

FIG. 6 demonstrate the difference between a crosstalk reduction strategy of the present disclosure and an existing cross-reduction strategy. In some existing technologies, a spacing S is kept between two adjacent signal lines SL to reduce crosstalk. In these technologies, crosstalk between adjacent signal lines SL is controlled by the spacing S. When the spacing S is increased, crosstalk is reduced. However, this strategy has its limitations as the spacing S cannot be increased indefinitely. The scaling down trend also comes with a large number of signal lines that require a lot of routing resources. A large spacing S can lead to low routing density and when routing resources within existing metal layers are exhausted, additional metal layers will be needed. That is contrary to the cost-reduction trend of reducing the number of metal layers in a routing structure, such as an RDL structure or an interposer. FIG. 6 also schematically illustrates an improved strategy according to the present disclosure. A ground line, which is electrically coupled to a ground voltage (also known as voltage source source (Vss)). Experimental and simulation data have established that while the spacing S still plays a role in the level of crosstalk. The insertion of the ground line can significantly reduce the crosstalk on top the crosstalk reduction provided by the spacing S. That is, when the spacing S is kept constant, crosstalk with the ground line insertion is substantially lower than that without. Additionally, when the crosstalk level is kept constant, the spacing S can be reduced with the insertion of the ground line between two adjacent signal lines. Besides the shielding effect provided by the intervening ground line, the inserted ground line may provide additional return current path.

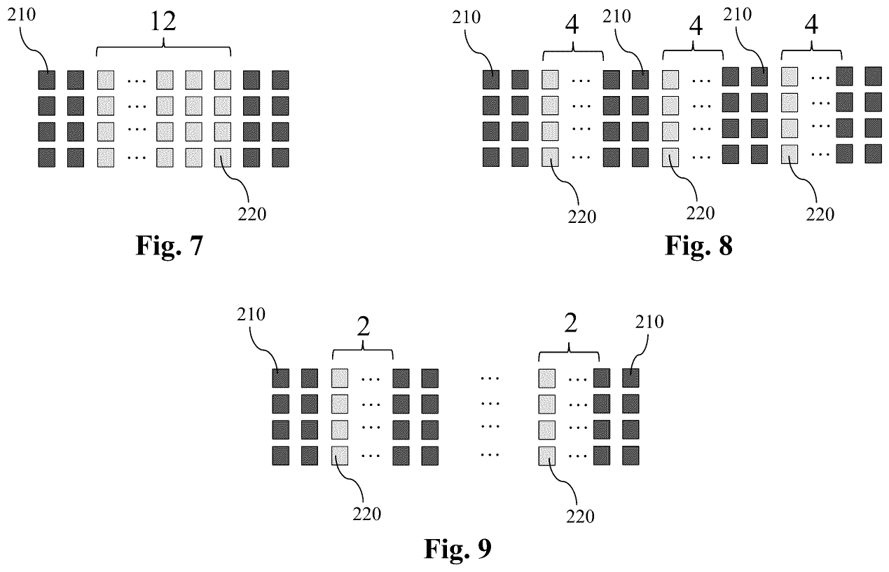

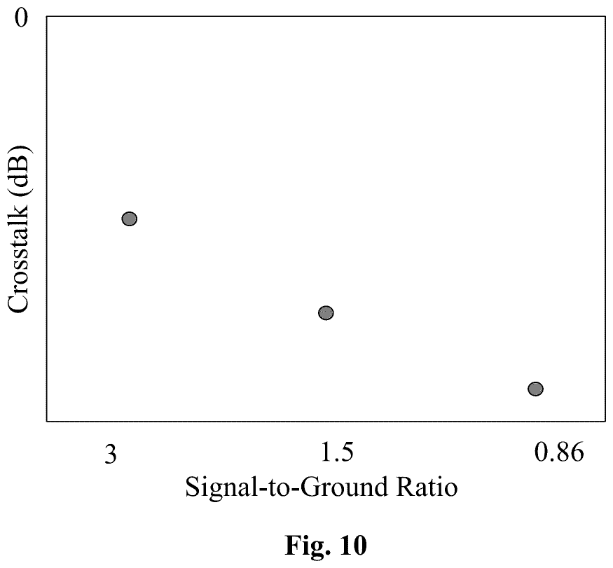

FIGS. 7, 8 and 9 illustrate effect of insertion of power/ground (P/G) contact features 210 among signal contact features 220. Depending on the construction and the fabrication processes, the contact features in FIGS. 7, 8 and 9 may correspond to the contact vias shown in FIG. 1 or the microbumps 26 shown in FIG. 2. As used herein, a power/ground (P/G) contact feature refers to be contact feature that is electrically coupled to a positive supply voltage (or voltage drain drain (Vdd)) or a ground voltage (or Vss). A signal contact feature refers to a contact feature that is electrically coupled to one or more transistor in one of the chips (or dies), similar to the chips A and B shown in FIG. 1 or the chips C, D and E shown in FIG. 2. FIGS. 7, 8 and 9 demonstrate that crosstalk can be reduced when a ratio (i.e., the SG ratio) of the number of the signal contact features 220 to the number of the P/G contact features 210 is reduced. FIG. 7 shows a contact feature pattern where twelve (12) columns of the signal contact features 220 are disposed between two 2-column groups of the P/G contact features 210. The SG ratio for the contact feature pattern in FIG. 7 can be calculated as twelve (12) divided by four (4), which equals 3. FIG. 8 shows a contact feature pattern where three 4-column groups of the signal contact features 220 are interleaved by four 2-column groups of the P/G contact features 210. The SG ratio for the contact feature pattern in FIG. 8 can be calculated as twelve (12) divided by eight (8), which equals 1.5. FIG. 9 shows a contact feature pattern where six 2-column groups of the signal contact features 220 are interleaved by seven 2-column groups of the P/G contact features 210. The SG ratio for the contact feature pattern in FIG. 9 can be calculated as twelve (12) divided by fourteen (14), which equals about 0.86. As indicated in FIG. 10, assuming uniform contact feature spacings, experimental and simulation results show that crosstalk for the contact feature pattern in FIG. 7 is the highest and crosstalk for the contact feature pattern in FIG. 9 is the lowest among the three patterns. When viewed as a whole, FIGS. 6-10 demonstrate the crosstalk reduction benefits of insertion of ground lines or P/G contact features. The contact feature patterns in FIGS. 8 and 9 are representative of contact feature patterns of the present disclosure for the purposes of reducing crosstalk. That is, according to the present disclosure, the SG ratio is below 1.5 to effectively reduce crosstalk.

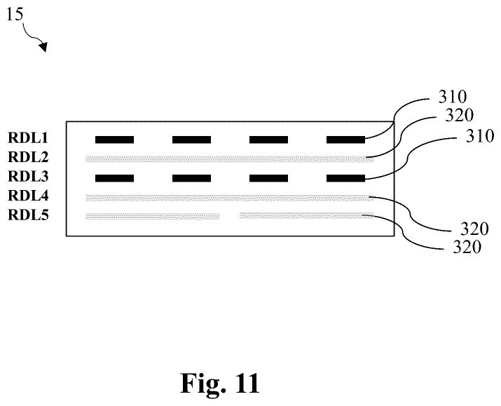

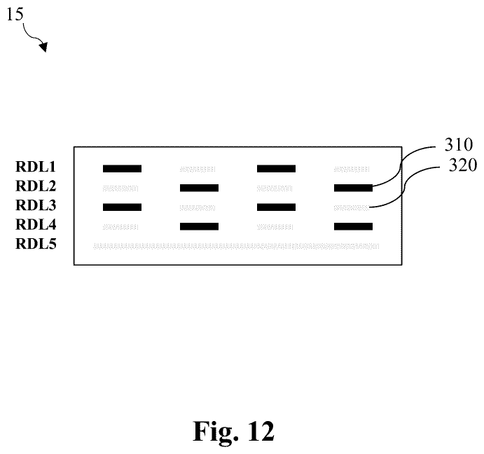

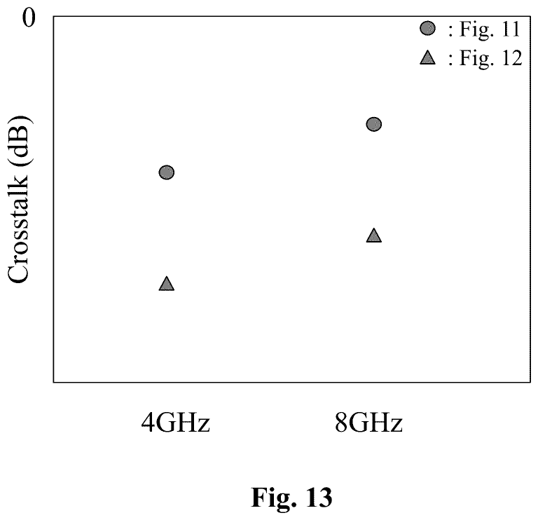

Insertion of ground lines may reduce crosstalk in RDL structures. FIGS. 11 and 12 illustrate different routing arrangements in an RDL structure 15 and FIG. 13 illustrates the comparative crosstalk levels for the routing arrangements in FIGS. 11 and 12. Each of FIGS. 11 and 12 illustrates a fragmentary view of the RDL structure 15 similar to the RDL structure 15 shown in FIG. 1. The RDL structure 15 in FIG. 11 or 12 includes five RDL metal layers—RDL 1, RDL 2, RDL 3, RDL 4, and RDL 5. It is noted that the RDL 1 is the first RDL metal layer closest to the chip(s) and the number “1” indicates that it is the first RDL metal layer formed in the manufacturing process. The RDL structure 15 in FIG. 11 includes four equally spaced signal lines 310 in the first RDL metal layer RDL 1 and the third RDL metal layer RDL 3. The RDL structure 15 in FIG. 11, however, does not include any ground lines in the second RDL metal layer RDL 2 and the fourth RDL metal layer RDL 4. The RDL structure 15 shown in FIG. 12 spreads out the eight signal lines in four RDL metal layers—RDL1, RDL2, RDL3, and RDL4. This allows one ground line 320 to be horizontally inserted between two adjacent signal lines 310 in a given RDL metal layer. Additionally, signal lines 310 in adjacent RDL metal layers are offset (not vertically aligned) such that signal lines in different RDL metal layers are also vertically spaced apart by one ground line 320. The insertion or interleaving of the ground lines 320 among the signal lines 310 is demonstrated in simulation and experiments to substantially lower the crosstalk level. Reference is now made to FIG. 13. Whether at a band frequency of 4 GHz or a band frequency of 8 GHz, the vertical and horizontal insertion of ground lines 320 between adjacent signal lines 310 can substantially reduce the crosstalk. The RDL structure 15 in FIG. 12 may be representative of an example RDL structure of the present disclosure for the purposes of reducing crosstalk.

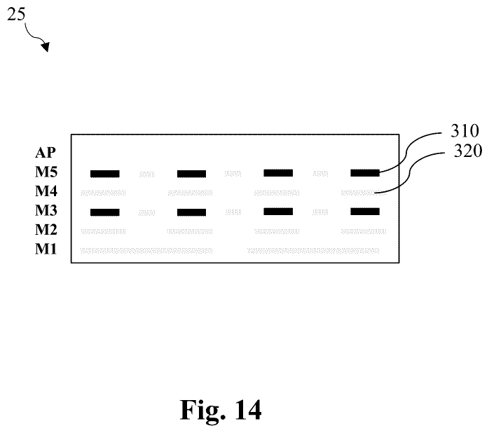

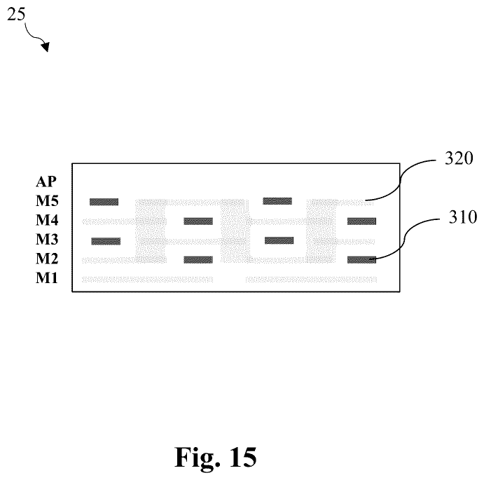

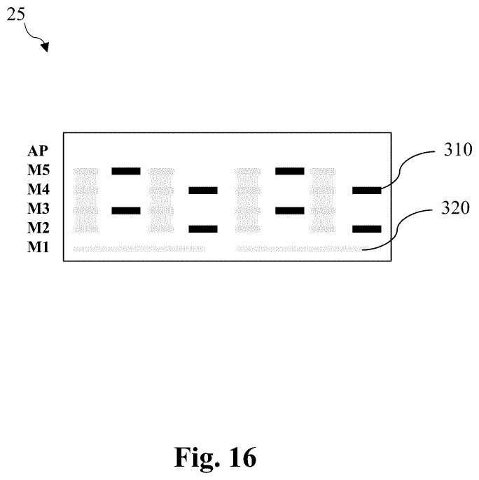

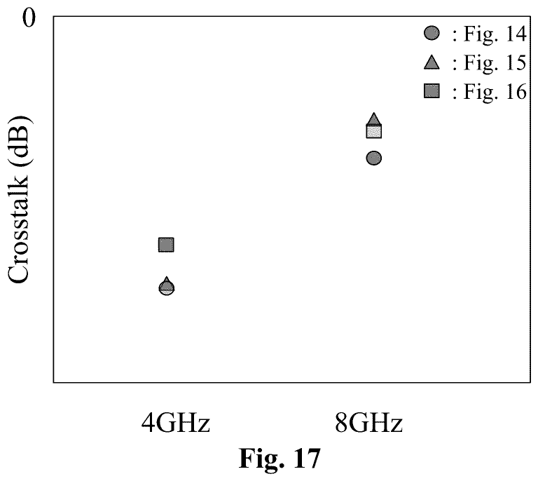

Insertion of ground lines may reduce crosstalk in interposers. FIGS. 14, 15 and 16 illustrate different routing arrangements in an interposer 25 and FIG. 17 illustrates the comparative crosstalk levels for the routing arrangements in FIGS. 14, 15 and 16. Each of FIGS. 14, 15 and 16 illustrates a fragmentary view of the interposer 25 similar to the interposer 25 shown in FIG. 2. The interposer 25 in FIG. 14, 15 or 16 includes five metal layers (M1, M2, M3, M4, and M5) and an aluminum pad (AP) layer. It is noted that the fifth metal layer M5 is closer to the chip(s) while the first metal layer M1 is farther away from the chip(s). The aluminum pads in the AP layer provide contacts to microbumps, such as the microbumps 26 shown in FIG. 2. Out of the five shown metal layers, the first metal layer M1 is manufactured first and the fifth metal layer M5 is manufactured last. In the interposer 25 in FIG. 14, signal lines 310 in the fifth metal layer M5 and the third metal layer M3 are horizontally spaced apart by one ground line 320. Additionally, signal lines 310 in the fifth metal layer M5 and the third metal layer M3 are also vertically spaced apart by ground lines 320 in the fourth metal layer M4. The interposer 25 in FIG. 15 include signal lines 310 spread out in the second metal layer M2, the third metal layer M3, the fourth metal layer M4, and the fifth metal layer M5. Vertically adjacent signal lines 310 are spaced apart by one ground line 320. Horizontally, the signal lines 310 are spaced far apart. Some of the ground lines 320 are vertically integrated using a through via. The interposer 25 shown in FIG. 16 also includes signal lines 310 spread out in the second metal layer M2, the third metal layer M3, the fourth metal layer M4, and the fifth metal layer M5 but vertically adjacent signal lines 310 are not spaced apart by intervening ground lines. The insertion or interleaving of the ground lines 320 among the signal lines 310 is demonstrated in simulation and experiments to substantially lower the crosstalk level. Reference is now made to FIG. 17. At a band frequency of 4 GHz or 8 GHz, the insertion of ground lines 320 between adjacent signal lines 310 as illustrated in FIG. 14, 15 or 16 can substantially reduce the crosstalk. It is noted the lack of vertical insertion of ground lines 320 in FIG. 16 gives the interposer 25 in FIG. 16 slightly inferior crosstalk reduction. The interposer 25 shown in FIGS. 14, 15 and 16 may be representative of example interposers of the present disclosure for the purposes of reducing crosstalk.

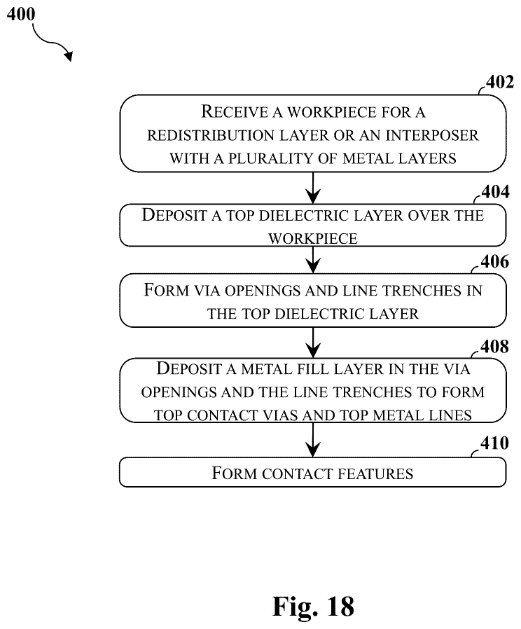

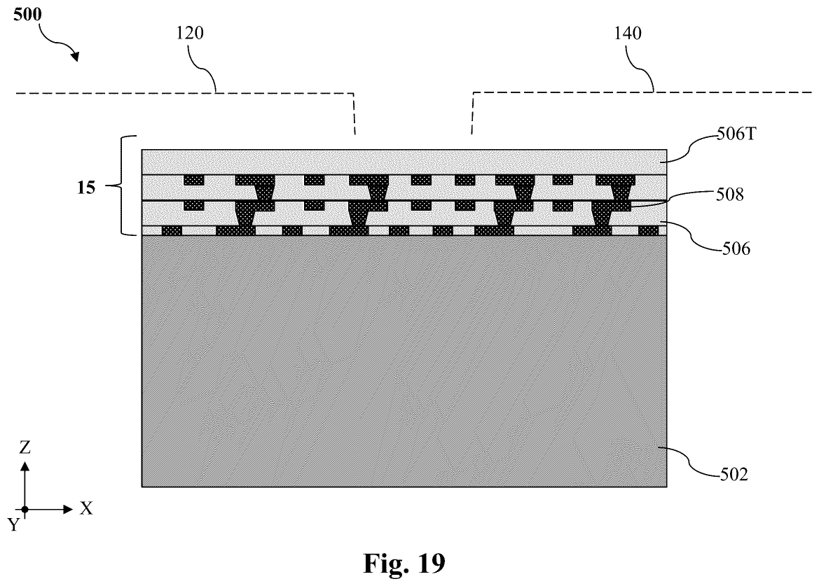

FIG. 18 illustrates a flowchart for a method 400 for forming a metal line in a top dielectric layer of an RDL structure similar to the RDL structure 15 shown in FIG. 1 or an interposer similar to the interposer 25 shown in FIG. 2. The method 400 is merely an example and is not intended to limit the present disclosure beyond what is explicitly recited in the claims. Additional operations may be performed before, during, and after the method 400, and some operations described can be replaced, eliminated, or moved around for additional embodiments of the method 400. The method 400 is described below in conjunction with FIGS. 19-24, which illustrate various diagrammatic cross-sectional views of a workpiece during intermediate steps of the method 400.

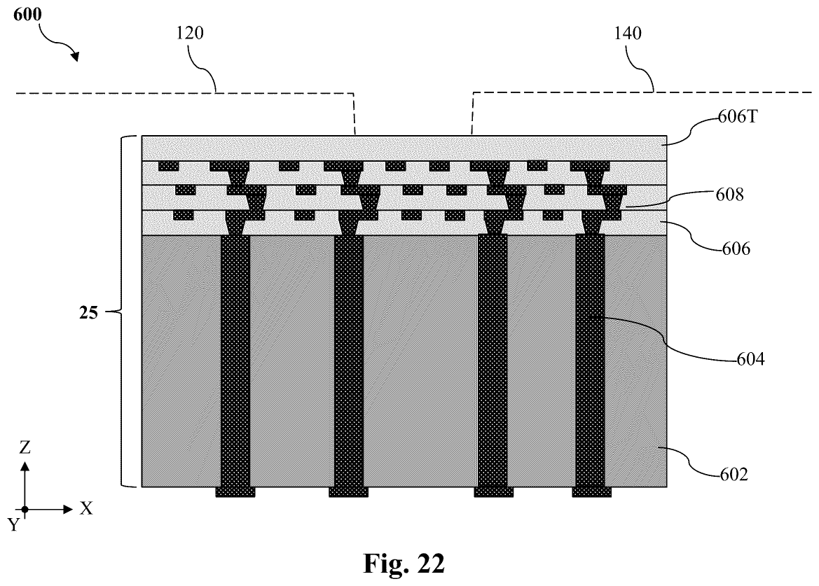

Referring to FIGS. 18, 19 and 22, method 400 includes a block 402 where a workpiece is received. The workpiece may be a workpiece 500 where an RDL structure 15 is being formed, as illustrated in FIG. 19 or a workpiece 600 where an interposer 25 is being formed, as illustrated in FIG. 22. The RDL structure 15 is similar to the RDL structure 15 shown in FIG. 1. The interposer 25 is similar to the interposer 25 shown in FIG. 2. Referring to FIG. 19, the workpiece 500 includes a carrier substrate 502, a plurality of dielectric layers 506, and a plurality of conductive features 508 in the plurality of dielectric layers 506. It is noted the RDL structure 15 in FIG. 19 is incomplete as more layers are to be formed thereof. The plurality of dielectric layers 506 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The plurality of conductive features 508 may include copper (Cu), cobalt (Co), ruthenium (Ru), nickel (Ni), or tungsten (W). Referring to FIG. 22, the workpiece 600 includes a silicon substrate 602, a plurality of through substrate vias (VIAs) 604 extending through the silicon substrate 602, a plurality of dielectric layer 606, and a plurality of conductive features 608 in the plurality of dielectric layers 606. It is noted the interposer 25 in FIG. 22 is incomplete as more layers are to be formed thereof. The plurality of dielectric layers 606 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The plurality of conductive features 608 may include copper (Cu), cobalt (Co), ruthenium (Ru), nickel (Ni), or tungsten (W).

Referring to FIGS. 18, 19 and 22, method 400 includes a block 404 where a top dielectric layer is deposited on the workpiece. With respect to the workpiece 500 in FIG. 19, block 404 deposits a top dielectric layer 506T. With respect to the workpiece 600 in FIG. 22, block 404 deposits a top dielectric layer 606T. The top dielectric layer 506T or 606T may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

Referring to FIG. 18, method 400 includes a block 406 where via openings and line trenches are formed in the top dielectric layer. In some embodiments, dual damascene processes may be used. For example, at least one hard mask layer is formed over the workpiece 500 shown in FIG. 19 or the workpiece 600 shown in FIG. 22. A first patterned photoresist layer is first used to etch the via openings. Then a second patterned photoresist layer is used to etch the line trenches.

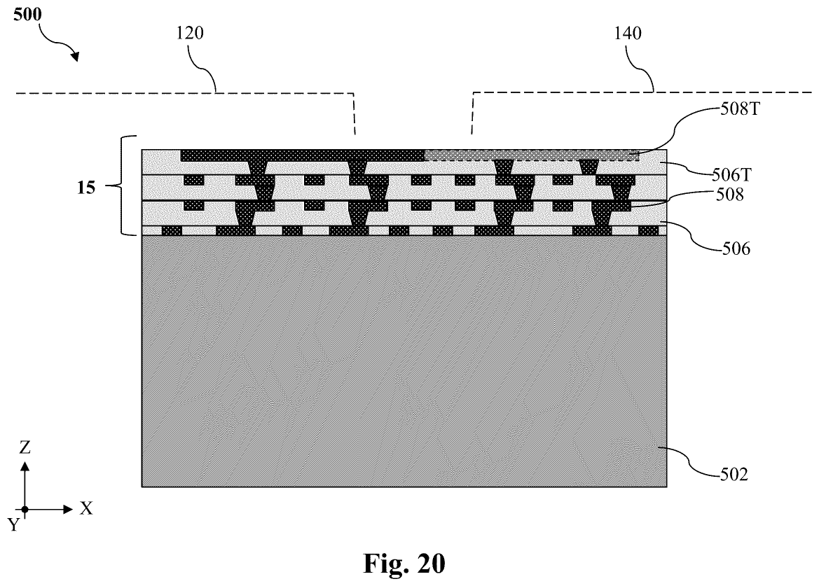

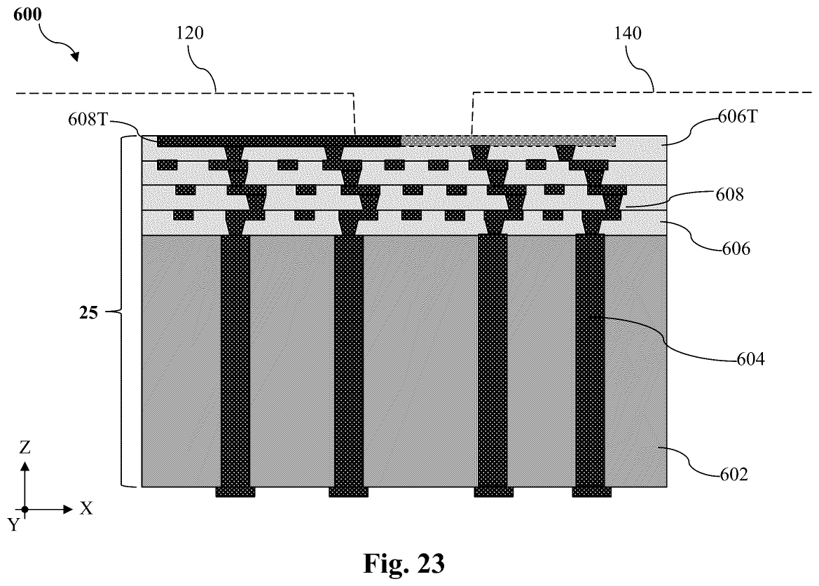

Referring to FIGS. 18, 20 and 23, method 400 includes a block 408 where a metal fill layer is deposited in the via openings and the line trenches to form top contact vias and top metal lines. After the formation of the via openings and the line trenches, a metal fill layer is deposited over the workpiece 500 shown in FIG. 20 or the workpiece 600 shown in FIG. 23. In some embodiments, the metal fill layer may include titanium (Ti), ruthenium (Ru), nickel (Ni), cobalt (Co), copper (Cu), molybdenum (Mo), tungsten (W), aluminum (Al), and/or other suitable materials. In one embodiment, the metal fill layer may include copper (Cu). To prevent electromigration, a barrier layer may be deposited over the via openings and line trenches before the deposition of the metal fill layer. The barrier layer may include titanium nitride (TiN), tantalum nitride (TaN), or tungsten nitride (WN). To deposit the metal fill layer, a seed layer may first be deposited using physical vapor deposition (PVD) or chemical vapor deposition (CVD). Then an electroplating process may be performed to form the metal fill layer over the seed layer. Operations at block 408 form a top metal line 508T shown in FIG. 20 or a top metal line 608T shown in FIG. 23. The top metal line 508T generally corresponds to one of the first metal line 132, the second metal line 134, or the third metal line 136. The top metal line 608T generally corresponds to one of the first metal line 142, the second metal line 144, and the third metal layer 146. Although the top metal line 508T or the top metal line 608T extends on the same X-Y plane to cross from below the first chip 120 to the second chip 140, the entirety of the top metal line 508T or top metal line 608T may not be disposed on the same Y-Z plane as a portion of the top metal line 508T or top metal line 608T may include two acute-angle turns or two right angle turns, as described above in conjunction with FIG. 3 or 4. In some alternative embodiments, the majority of the top metal line 508T or top metal line 608T may extend along the same YZ plane when the third routing structure shown in FIG. 5 is adopted. It is noted that dotted lines are used to denote the portions of the top metal line 508T or the top metal line 608T that are out of the cross-sectional plane. After the formation of the contact vias and metal lines, a planarization process, such as a chemical mechanical polishing (CMP) process, may be performed to remove the excess materials.

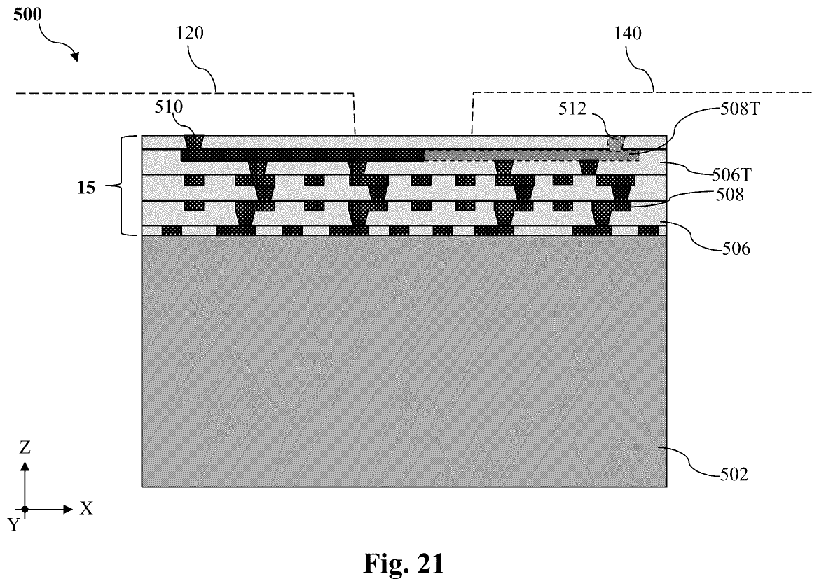

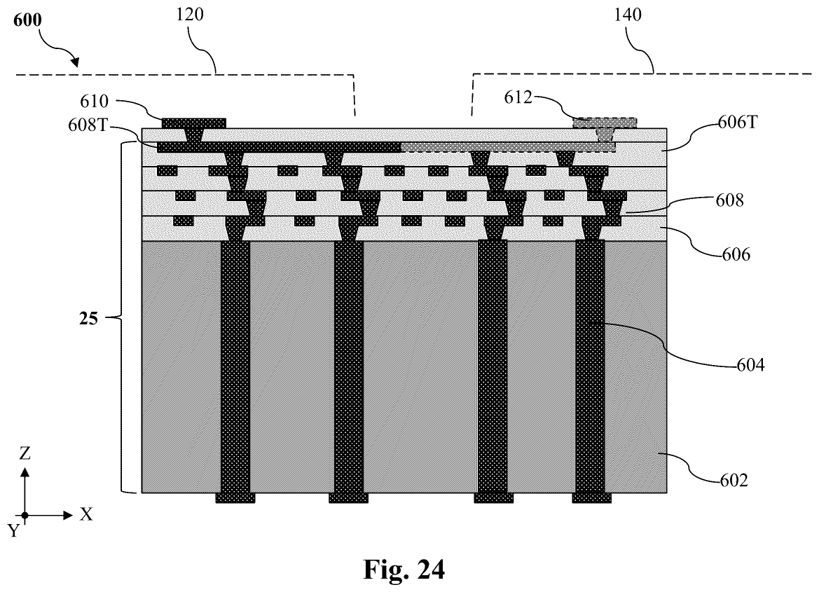

Referring to FIGS. 18, 21 and 24, method 400 includes a block 410 where contact features are formed over the top metal lines. Depending on the design needs, the contact features may be top contact vias or contact pads. With respect to the workpiece 500 in FIG. 21, block 410 forms a first top contact via 510 and a second top contact via 512 over the top metal line 508T. The first top contact via 510 is configured to be bonded to the first chip 120 and the second top contact via 512 is configured to be bonded to the second chip 140. With respect to the workpiece 600 in FIG. 24, block 410 forms a first contact pad 610 and a second contact pad 612 over the top metal line 608T. The first contact pad 610 is configured to be bonded to the first chip 120 and the second contact pad 612 is configured to be bonded to the second chip 140. As shown in FIGS. 21 and 24, operations at block 410 include depositing at least one dielectric layer over the top metal line 508T or 608T, formation of via openings through the at least one dielectric layer, depositing of a metal fill layer over the via openings, and patterning of the metal fill layer.

Method 400 may include further processes. For example, with respect to the workpiece 500, the RDL structure 15 is bonded to the first chip 120 and the second chip 140 using, for example, direct bonding. After removal of the carrier substrate 502, the RDL structure 15, along with the first chip 120 and the second chip 140, may be bonded to a substrate by way of C4 bumps. The resulting structure may be similar to the semiconductor device package structure 10 shown in FIG. 1. With respect to the workpiece 600, a front side of the interposer 25 is bonded to the first chip 120 and the second chip 140 by way of microbumps and the backside of the interposer 25 is bonded to a substrate by way of C4 bumps. The resulting structure may be similar to the semiconductor device package structure 20 shown in FIG. 2.

The present disclosure provides many embodiments. In one aspect, the present disclosure provides a semiconductor package. The semiconductor package includes a routing structure, a first die and a second die disposed over the routing structure, a first array of contact features disposed along a first direction and electrically coupling the first die to the routing structure, and a second array of contact features disposed along the first direction and electrically coupling the second die to the routing structure. The routing structure includes a plurality of metal lines and each of the plurality of metal lines electrically connects one of the first array of contact features and one of the second array of contact features. Each of the plurality of metal lines includes at least two 90-degree turns on a horizontal plane.

In some embodiments, wherein each of the plurality of metal lines includes a portion that is not disposed below the first die or the second die and the portion forms an acute angle with the first direction. In some implementations, the first array of contact features is aligned with the second array of contact features along the first direction. In some instances, the first array of contact features is offset with the second array of contact features along the first direction. In some embodiments, the routing structure includes a redistribution layer (RDL) structure. In some instances, the first array of contact features include first contact vias and the second array of contact features include second contact vias. In some embodiments, the routing structure includes an interposer. In some embodiments, the first array of contact features include first microbumps and the second array of contact features include second microbumps. In some instances, the first die includes a plurality of transistors and the first array of contact features include power/ground (P/G) contact features coupled to a positive supply voltage or a ground voltage, and signal contact features coupled to the plurality of transistors. A ratio of the signal contact features to the P/G contact features is smaller than 1.5.

In another aspect, the present disclosure provides a package structure. The package structure includes a routing structure that includes a top surface and a first metal layer adjacent the top surface, and a first die and a second die disposed side-by-side over the top surface of the routing structure. The first metal layer includes a first plurality of signal lines interleaved by a first plurality of ground lines.

In some embodiments, the first plurality of ground lines are coupled to a ground voltage. In some implementations, the routing structure further includes a second metal layer directly below the first metal layer and the second metal layer includes a second plurality of ground lines. Each of the second plurality of ground lines is disposed below one of the first plurality of signal lines. In some instances, the routing structure includes a redistribution layer (RDL) structure. In some embodiments, the first die and the second die are electrically coupled to the routing structure by way of contact vias. In some implementations, the routing structure includes an interposer. In some instances, the first die and the second die are electrically coupled to the routing structure by way of microbumps.

In still another aspect, the present disclosure provides a method. The method includes receiving a workpiece including a plurality of contact via and metal lines, depositing a dielectric layer over the workpiece, patterning a line trench in the dielectric layer, depositing a metal fill layer in the line trench to form a metal line, forming a first contact feature disposed directly over a first end of the metal line, and forming a second contact feature disposed directly over a second end of the metal line. The metal line includes at least two 90-degree turns on a horizontal plane.

In some embodiments, the metal line further includes two acute-angle turns on the horizontal plane. In some implementations, the method further includes bonding a first chip to the first contact feature, and bonding a second chip to the second contact feature. In some instances, the bonding of the first chip to the first contact feature or the bonding of the second chip to the second contact feature includes use of a microbump.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a routing structure;
a first die and a second die disposed over the routing structure;
a first array of contact features disposed along a first direction and electrically coupling the first die to the routing structure; and
a second array of contact features disposed along the first direction and electrically coupling the second die to the routing structure,
wherein the routing structure comprises a plurality of metal lines and each of the plurality of metal lines electrically connects one of the first array of contact features and one of the second array of contact features,
wherein each of the plurality of metal lines comprises at least two 90-degree turns on a horizontal plane.

2. The semiconductor package of claim 1,
wherein each of the plurality of metal lines comprises a portion that is not disposed below the first die or the second die,
wherein the portion forms an acute angle with the first direction.

3. The semiconductor package of claim 1, wherein the first array of contact features is aligned with the second array of contact features along the first direction.

4. The semiconductor package of claim 1, wherein the first array of contact features is offset with the second array of contact features along the first direction.

5. The semiconductor package of claim 1, wherein the routing structure comprises a redistribution layer (RDL) structure.

6. The semiconductor package of claim 5,
wherein the first array of contact features comprise first contact vias,
wherein the second array of contact features comprise second contact vias.

7. The semiconductor package of claim 1, wherein the routing structure comprises an interposer.

8. The semiconductor package of claim 7,
wherein the first array of contact features comprise first microbumps,
wherein the second array of contact features comprise second microbumps.

9. The semiconductor package of claim 1,
wherein the first die comprises a plurality of transistors,
wherein the first array of contact features include:
power/ground (P/G) contact features coupled to a positive supply voltage or a ground voltage, and
signal contact features coupled to the plurality of transistors,
wherein a ratio of the signal contact features to the P/G contact features is smaller than 1.5.

10. A package structure, comprising:
a routing structure comprising:
a top surface, and
a first metal layer adjacent the top surface; and
a first die and a second die disposed side-by-side over the top surface of the routing structure,
wherein the first metal layer comprises a first plurality of signal lines interleaved by a first plurality of ground lines.

11. The package structure of claim 10, wherein the first plurality of ground lines are coupled to a ground voltage.

12. The package structure of claim 10,
wherein the routing structure further comprises a second metal layer directly below the first metal layer,
wherein the second metal layer comprises a second plurality of ground lines,
wherein each of the second plurality of ground lines is disposed below one of the first plurality of signal lines.

13. The package structure of claim 10, wherein the routing structure comprises a redistribution layer (RDL) structure.

14. The package structure of claim 13, wherein the first die and the second die are electrically coupled to the routing structure by way of contact vias.

15. The package structure of claim 10, wherein the routing structure comprises an interposer.

16. The package structure of claim 15, wherein the first die and the second die are electrically coupled to the routing structure by way of microbumps.

17. A method, comprising:
receiving a workpiece comprising a plurality of contact via and metal lines;
depositing a dielectric layer over the workpiece;
patterning a line trench in the dielectric layer;
depositing a metal fill layer in the line trench to form a metal line;
forming a first contact feature disposed directly over a first end of the metal line; and
forming a second contact feature disposed directly over a second end of the metal line,
wherein the metal line comprises at least two 90-degree turns on a horizontal plane.

18. The method of claim 17, wherein the metal line further comprises two acute-angle turns on the horizontal plane.

19. The method of claim 17, further comprising:
bonding a first chip to the first contact feature; and
bonding a second chip to the second contact feature.

20. The method of claim 19, wherein the bonding of the first chip to the first contact feature or the bonding of the second chip to the second contact feature comprises use of a microbump.
